(19) United States
(12) Patent Application Publication
(10) Pub. No.: US 2002/0137356 A1
(43) Pub. Date: Sep. 26, 2002

(54) Metallization process of in-situ forming titanium nitride and tungsten nitride in tungsten plug

(76) Inventors: Chi Tung Huang, Hsinchu (TW); Jui Neng Tu, Kaohsiung Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/811,608

(22) Filed: Mar. 20, 2001

(51) Int. Cl. H01L 21/302

(52) U.S. Cl. 438/740

(57) ABSTRACT

The present invention provides a metallization process of in-situ forming titanium nitride and tungsten nitride in a tungsten plug. In the present invention, a dielectric layer is formed on the surface of a substrate, a via hole is formed on the dielectric layer, and a titanium layer is deposited on the surfaces of the dielectric layer and the via hole. Next, a titanium nitride passivation, a barrier layer of tungsten nitride, and a tungsten plug are formed in turn on the titanium layer in the same chamber. Finally, part of the tungsten layer on the surface is removed to leave only the tungsten in the via hole. A tungsten plug is thus formed. The present invention can decrease the count of required chambers and reduce the production cost.

### FIELD OF THE INVENTION

The present invention relates to a metallization process of integrated circuit (IC) and, more particularly, to a metallization process of forming titanium nitride and tungsten nitride in a tungsten plug.

### BACKGROUND OF THE INVENTION

The metallization process of IC has two primary objects. One is to form contacts for gates, sources, and drains of semiconductor devices using leads. The other is to connect all these leads already contacting individual semiconductor devices to form a complete circuit through the interconnection function of these leads according to the circuit layout.

Among all the metallization processes, the most commonly seen is the metallization process of a tungsten plug. With the process of forming a via plug as an example, as shown in FIG. 1, a via hole 14 is formed on a dielectric layer 12 on the surface of a substrate 10. A titanium layer 16 is then deposited on the surface of the dielectric layer 12 and on the surface of the via hole 14. Next, a titanium nitride layer 18 is sputtered on the whole surface. Finally, a tungsten layer 20 is deposited to fill the via hole 14. The tungsten layer 20 covering the surface of the dielectric layer 12 is then removed to leave only the tungsten in the via hole 14. The fabrication process of a tungsten plug is thus completed.

However, the deposition of titanium, the sputtering of titanium nitride, and the deposition of tungsten in the above process are performed in different chambers and at least three chambers must be used. Moreover, the weak point of the sputtered titanium nitride might have problem such as volcano when applied to the fabrication process below 0.25 micrometers. If other advanced physical vapor deposition (PVD) or chemical vapor deposition (CVD) processes are used to deposit titanium nitride, advanced chambers must be purchased beforehand, resulting in the increase of the production cost.

Accordingly, the present invention aims to propose a new metallization process of a tungsten plug to resolve the above problems in the prior art.

### SUMMARY OF THE INVENTION

The primary object of the present invention is to provide a metallization process of a tungsten plug, which process integrates the process of plasma nitridation, the deposition of tungsten nitride, and the filling of tungsten plug to with one chamber, thereby extending the application of tungsten chemical vapor deposition (WCVD) chamber and reducing the count of required chambers. Therefore, the present invention can achieve the same objects by using fewer chambers.

Another object of the present invention is to provide a metallization process of a tungsten plug applicable to the fabrication process below 0.25 micrometers. It is not necessary to purchase additional machines. Therefore, the production cost can be reduced.

To achieve the above objects, in the present invention, a dielectric layer is formed on the surface of a substrate, a via hole is formed in the dielectric layer, and a titanium layer is deposited on the surfaces of the dielectric layer and the via hole by sputtering. Next, a titanium nitride passivation is formed on the surface of the titanium layer by using the plasma nitridation treatment. A barrier layer of tungsten nitride and a tungsten layer are deposited in turn for forming on the titanium nitride passivation in the same chamber. Finally, the tungsten layer on field area is removed to leave the tungsten only in the via hole, thus a tungsten plug is formed.

The objects and advantages of the present invention will be more readily understood from the following detailed description when read in conjunction with the appended drawings, in which:

### BRIEF DESCRIPTION OF THE DRAWINGS

FIG. 1 is a metallization process of forming a tungsten plug in the prior art;

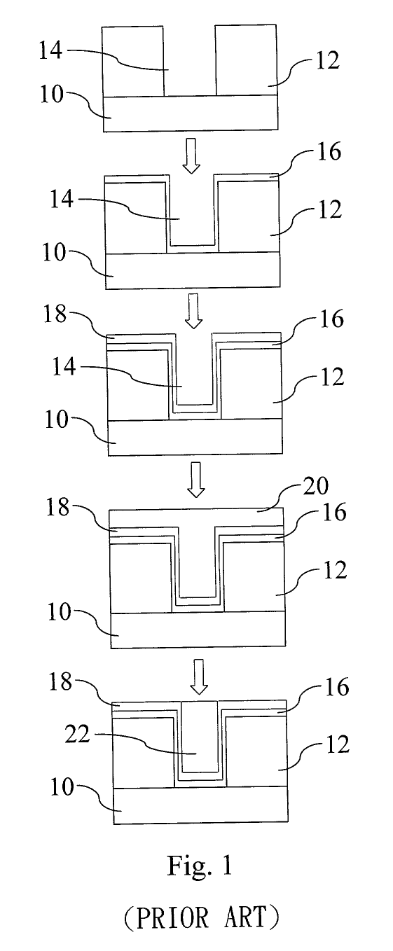

FIG. 2 is the fabrication process of the present invention; and

FIG. 3 is a comparison table of the counts of chambers used in the metallization processes of a tungsten plug according to the prior art and the present invention.

### DETAILED DESCRIPTION OF THE PREFERRED EMBODIMENTS

The present invention is characterized in that the plasma nitridation of titanium, the forming of a barrier layer, and the deposition of tungsten are insitu completed in a single WCVD chamber to reduce the count of required chambers and to be applicable to all kinds of fabrication processes.

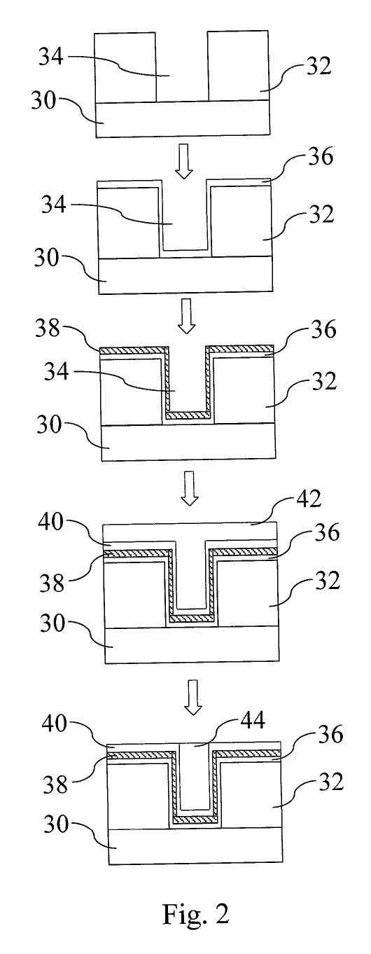

The metallization process of a tungsten plug is extensively used in the contact plug and the via plug. The same fabrication process is performed no matter what kinds of plug. As shown in FIG. 2, the metallization process of insitu forming titanium nitride and tungsten nitride in a tungsten plug in the same chamber comprises the following steps. First, a substrate 30 is provided. Usually, the dielectric layer 32 on the surface thereof is a silicon dioxide layer. A via hole 34 is formed in the dielectric layer 32. A titanium layer 36 is deposited on the surfaces of the dielectric layer 32 and the via hole 34 by sputtering. The above substrate is composed of silicon or metallic material.

Next, a titanium nitride passivation 38 is formed on the surface of the titanium layer 36 using the plasma nitridation in the same chamber. In this step, a gas having nitrogen (e.g., nitrogen or ammonia) is first led in the chamber and the plasma is formed by the applied power say on the shower head or on the coil around the chamber. The plasma reacts with the titanium layer 36 and therefore forms the titanium nitride passivation 38. The plasma nitridation can be carried out under 0.5-100 Torr chamber pressure and with applied power of 50-1000 W. But not all of the titanium is depleted. Part of the titanium layer 36 is reserved for reducing the resistance. A barrier layer of tungsten nitride 40 is then deposited on the titanium nitride passivation 38 using the thermal CVD or the plasma enhanced CVD (PECVD). The thermal CVD for forming tungsten nitride can be carried out at 350-500° C. and under 3-250 Torr by flowing gases of WF₆ and NH₃. Finally, a tungsten layer 42 is deposited on the barrier layer of tungsten nitride 40, and part of the tungsten layer 42 on the surface is removed by etching or chemical mechanical polishing (CMP) to leave only the tungsten in the via hole 34. A tungsten plug 44 is thus formed.

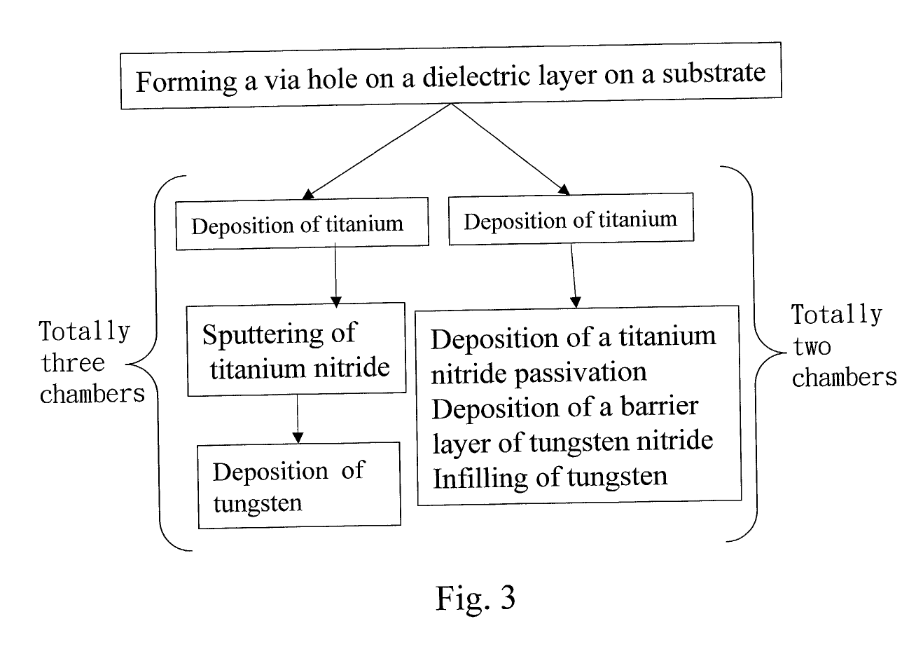

The above steps of forming the titanium nitride 38, the barrier layer of tungsten nitride 40, and the tungsten layer 42 are integrated to be performed in the same chamber so that only two chambers are required for the complete metallization process of the tungsten plug 44. As shown in FIG. 3, the deposition of titanium, the sputtering of titanium nitride, and the deposition of tungsten are respectively performed in different chambers in the prior art. Therefore, three chambers are required. In the present invention, a chamber is used for the deposition of titanium. Other steps are performed in another chamber. Therefore, only two chambers are required. That is, the same objects can be achieved by using fewer chambers in the present invention as compared to the prior art.

In addition to the plasma nitridation, the deposition of tungsten nitride, and the filling of tungsten plug are integrated to be performed in the same chamber so as to extend the application of the WCVD chamber and to reduce the count of required chambers. The present invention can be extensively used in the metallization processes of all kinds of tungsten plugs, especially the metallization process below 0.25 micrometers. It is not necessary to purchase additional advanced PVD or CVD chambers for depositing titanium nitride. Therefore, the production cost can be reduced.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A metallization process of in-situ forming titanium nitride, tungsten nitride and tungsten plug in the same chamber, comprising the steps of:
providing a substrate with a via hole formed on a dielectric layer on the surface of said substrate;
depositing a titanium layer on the surfaces of said dielectric layer and said via hole;
forming a titanium nitride passivation on the surface of said titanium layer by means of plasma nitridation and depositing a tungsten layer on said titanium nitride passivation in the same chamber; and
removing part of said tungsten layer by etching to leave only the tungsten in said via hole so as to form the tungsten plug.

2. The metallization process as claimed in claim 1, wherein a barrier layer of tungsten nitride can be further deposited in the same chamber after said titanium nitride passivation is formed.

3. The metallization process as claimed in claim 2, wherein said barrier layer of tungsten nitride is formed by means of thermal chemical vapor deposition or plasma enhanced chemical vapor deposition.

4. The metallization process as claimed in claim 1, wherein said substrate is selected from the groups composed of silicon and metallic material.
